(19) United States
(12) Patent Application Publication
(10) Pub. No.: US 2024/0394433 A1
(43) Pub. Date: Nov. 28, 2024

(54) APPLICATION PROGRAMMING INTERFACE SIMULATION SYSTEM AND METHOD

(71) Applicant: Capital One Services, LLC, McLean, VA (US)

(72) Inventors: Matthew Reiss, Richmond, VA (US); Binoy Manikoth, Glen Allen, VA (US); Akshat Bhatnagar, Henrico, VA (US); Christopher Rosswog, North Chesterfield, VA (US); Zachary Tsouprakos, West Islip, NY (US); Gaurav Singh, Glen Allen, VA (US)

(21) Appl. No.: 18/323,930

(22) Filed: May 25, 2023

(51) Int. Cl. G06F 30/20; G06F 9/54

(52) U.S. Cl. CPC G06F 30/20; G06F 9/541

(57) ABSTRACT

Techniques for generating a simulated application programming interface (API) may include generating simulations of APIs that provide stateful interactions. The simulations may be generated based on API specifications and/or other API parameters (e.g. from a user). The API simulations may be deployed to individual tenancies that provide dedicated resources for the simulation. The simulations may be further secured by anonymizing or scrubbing data used in the simulation by removing non-public information from data provided for the simulation. Additionally, or alternatively, dummy data may be generated that is free of non-public information. A demo site (e.g., a mocked frontend) may be generated that facilitates access to the simulated API and allow a real-world evaluation of the simulated API by a user.

### FIELD OF USE

Aspects of the disclosure relate generally to the simulation of Application Programming Interfaces (APIs), and more specifically to API simulations with stateful interactions.

### BACKGROUND

Current API simulations are directed to testing solutions that are limited to stateless interactions. Further, such solutions generally require a user to provide a developed user interface for interaction with the simulated API. These solutions lack support for stateful transactions and/or simulated interfaces for interacting with the simulated API.

Aspects described herein may address these and other problems, and generally improve the simulation of APIs by providing intelligent, mocked transactions.

### SUMMARY

The following presents a simplified summary of various aspects described herein. This summary is not an extensive overview, and is not intended to identify key or critical elements or to delineate the scope of the claims. The following summary merely presents some concepts in a simplified form as an introductory prelude to the more detailed description provided below. Corresponding apparatus, systems, and computer-readable media are also within the scope of the disclosure.

Aspects of the present disclosure provide simulation of one or more Application Programming Interfaces (APIs), which may include API simulations with stateful interactions. The simulated APIs according to aspects of the disclosure may be configured based on API specifications, which may be predetermined and/or provided by the user. Further aspects may include individual tenancies for the respective simulated APIs that provide dedicated resources for the simulation. The solutions may also provide a secure solution by anonymizing data used in the simulation.

Conventional technologies lack stateful solutions, which results in static simulations that are unable to mimic real-world applications of the API. Aspects of the present disclosure provide the benefit of real-world interactions provided by stateful response and the security of anonymized data and dedicated hardware for the individual simulation environments. These features, along with many others, are discussed in greater detail below.

### BRIEF DESCRIPTION OF THE DRAWINGS

The present disclosure is described by way of example and not limited in the accompanying figures in which like reference numerals indicate similar elements and in which:

FIG. 1 shows an example of a control processing system in which one or more aspects described herein may be implemented;

FIG. 2 shows an example computing device in accordance with one or more aspects described herein;

FIG. 3 shows an example simulation system in accordance with one or more aspects described herein; and

FIG. 4 shows a flow chart of a process for generating a simulated API according to one or more aspects of the disclosure.

### DETAILED DESCRIPTION

In the following description of the various embodiments, reference is made to the accompanying drawings, which form a part hereof, and in which is shown by way of illustration various embodiments in which aspects of the disclosure may be practiced. It is to be understood that other embodiments may be utilized and structural and functional modifications may be made without departing from the scope of the present disclosure. Aspects of the disclosure are capable of other embodiments and of being practiced or being carried out in various ways. In addition, it is to be understood that the phraseology and terminology used herein are for the purpose of description and should not be regarded as limiting. Rather, the phrases and terms used herein are to be given their broadest interpretation and meaning.

By way of introduction, aspects discussed herein may relate to methods and techniques for simulating one or more Application Programming Interfaces (APIs), and more specifically to API simulations that advantageously provide stateful interactions that mimic real-world interactions and environments. Conventionally, API technologies are limited in both breadth and functionality by providing only stateless solutions which are limited to static simulations. Such technologies are unable to mimic real-world applications of the API. Conventional technologies also lack mock interfaces that allow for the user to interact with the simulated API. The lack of a mock interface and a stateful interaction prevents the conventional technologies from providing the user with a real-world, accurate environment in which to evaluate the API. Further, without the anonymization capabilities and dedicated tenancy environments for the simulated API of the aspects of the present disclosure, the conventional technologies lack a secure and contained configuration for the simulated APIs.

Systems and methods as described herein may include simulations of one or more APIs, which may include stateful API simulations that advantageously provide stateful interactions that mimic real-world interactions and environments. In providing stateful interactions, the systems and method of the disclosure simulate transactions of increased complexity (e.g., account management/account creation), where the conventional technologies are limited to basic, static transactions.

The systems and methods may further include anonymization configurations that anonymize user data and dedicated tenancy environments for the simulated API, which advantageously provides a secure and contained configuration for the simulated APIs. The simulated APIs may be accessed and evaluated using a mock interface that is configured to mimic the user's intended application and environment in which the API is to be deployed. This advantageously allows for the user to evaluate the simulated API without requiring the user build and supply a developed frontend interface.

Advantageously, the individual tenancies for the respective simulated APIs may be supported by dedicated resources of the underlying computing device. This configuration advantageously provides additional improvements to the functioning of the computing device by improving the security of the individual simulations, including isolating sensitive data therein, while also improving the security of underlying computing device supporting the simulations by restricting external access to limited sets of compartmentalized resources of the computing device.

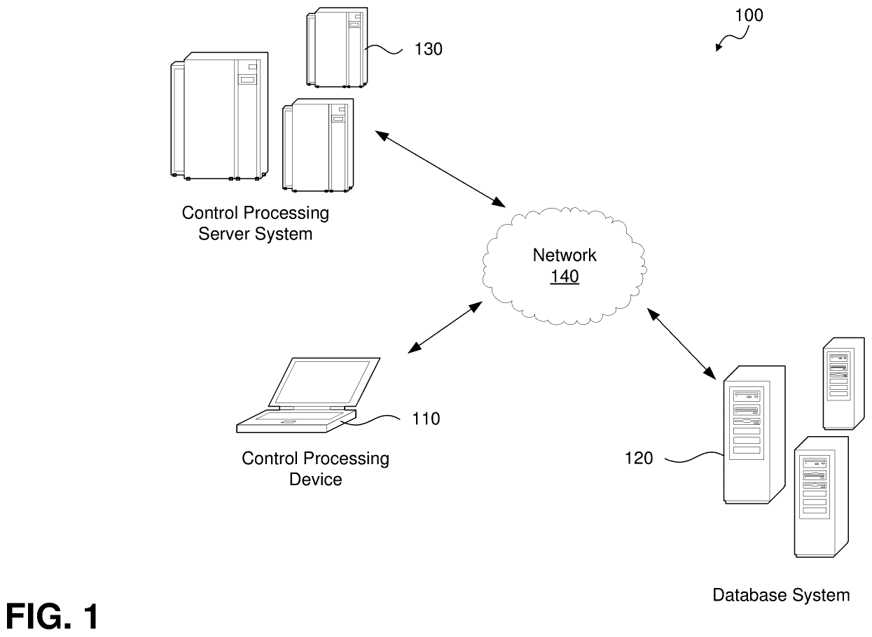

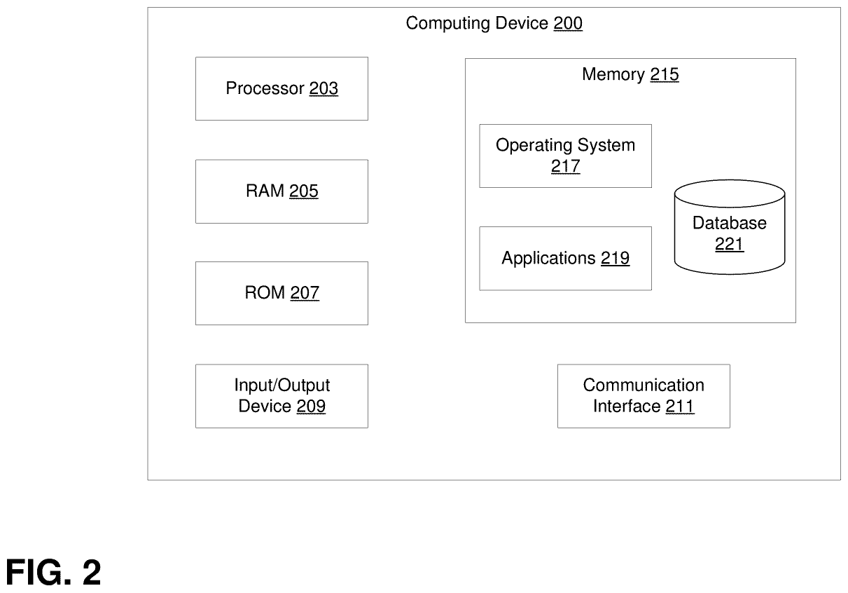

FIG. 1 shows a system 100. The system 100 may include at least one device 110, at least one database system 120, and/or at least one server system 130 in communication via a network 140. It will be appreciated that the network connections shown are illustrative and any means of establishing a communications link between the computers may be used. The existence of any of various network protocols such as Transmission Control Protocol/Internet Protocol (TCP/IP), Ethernet, File Transfer Protocol (FTP), Hypertext Transfer Protocol (HTTP) and the like, and of various wireless communication technologies such as Global System for Mobile Communications (GSM), Code-division multiple access (CDMA), WiFi, and Long Term Evolution (LTE), and/or 5G , is presumed, and the various computing devices described herein may be configured to communicate using any of these network protocols or technologies. Any of the devices and systems described herein may be implemented, in whole or in part, using one or more computing systems described with respect to FIG. 2.

Devices 110 may perform client-side actions as described herein. Database systems 120 may perform data retrieval and storage actions as described herein, such as the retrieval and storage of request-response datasets, API specifications, API parameters and/or other API data, and/or other information. Databases may include, but are not limited to relational databases, hierarchical databases, distributed databases, in-memory databases, flat file databases, Extensible Markup Language (XML) databases, NoSQL databases, graph databases, and/or a combination thereof. Server systems 130 may perform server-side actions as described herein, such as the data retrieval and storage actions (e.g. of API specifications and/or other API data). The server system 130 may be configured as a cloud-computing environment configured to perform the processes described herein. The network 140 may include a local area network (LAN), a wide area network (WAN), a wireless telecommunications network, and/or any other communication network or combination thereof. Although aspects may be described with a particular device of the system 100 performing data processing, the processing may be additionally or alternatively performed by one or more other devices of the system 100. In some aspects, the processing may be distributed across two or more of the device 110, the system 120, and the system 130.

The data transferred to and from various computing devices in system 100 may include secure and sensitive data, such as confidential documents, customer personally identifiable information, and account data. Therefore, it may be desirable to protect transmissions of such data using secure network protocols and encryption, and/or to protect the integrity of the data when stored on the various computing devices. For example, a file-based integration scheme or a service-based integration scheme may be utilized for transmitting data between the various computing devices. Data may be transmitted using various network communication protocols. Secure data transmission protocols and/or encryption may be used in file transfers to protect the integrity of the data, for example, File Transfer Protocol (FTP), Secure File Transfer Protocol (SFTP), and/or Pretty Good Privacy (PGP) encryption. In many embodiments, one or more web services may be implemented within the various computing devices. Web services may be accessed by authorized external devices and users to support input, extraction, and manipulation of data between the various computing devices in the system 100. Web services built to support a personalized display system may be cross-domain and/or cross-platform, and may be built for enterprise use. Data may be transmitted using the Secure Sockets Layer (SSL) or Transport Layer Security (TLS) protocol to provide secure connections between the computing devices. Web services may be implemented using the WS-Security standard, providing for secure SOAP messages using XML encryption. Specialized hardware may be used to provide secure web services. For example, secure network appliances may include built-in features such as hardware-accelerated SSL and Hypertext Transfer Protocol Secure (HTTPS), WS-Security, and/or firewalls. Such specialized hardware may be installed and configured in the system 100 in front of one or more computing devices such that any external devices may communicate directly with the specialized hardware.

Turning now to FIG. 2, a computing device 200 that may be used with one or more of the computational systems is described. The computing device 200 may include a processor 203 for controlling overall operation of the computing device 200 and its associated components, including random access memory (RAM) 205, read-only memory (ROM) 207, input/output (I/O) device 209, communication interface 211, and/or memory 215. A data bus may interconnect processor(s) 203, RAM 205, ROM 207, memory 215, I/O device 209, and/or communication interface 211. In some embodiments, computing device 200 may represent, be incorporated in, and/or include various devices such as a desktop computer; a computer server; a mobile device, such as a laptop computer, a tablet computer, a smart phone, any other types of mobile computing devices and the like; and/or any other type of data processing device.

I/O device 209 may include a microphone, keypad, touch screen, and/or stylus through which a user of the computing device 200 may provide input, and may also include one or more of: a speaker for providing audio output and a video display device for providing textual, audiovisual, and/or graphical output. Software may be stored within memory 215 to provide instructions to processor 203 allowing computing device 200 to perform various actions. For example, memory 215 may store software used by the computing device 200, such as an operating system 217, application programs 219, and/or an associated internal database 221. The various hardware memory units in memory 215 may include volatile and nonvolatile, removable and non-removable media implemented in any method or technology for storage of information such as computer-readable instructions, data structures, program modules, or other data. Memory 215 may include one or more physical persistent memory devices and/or one or more non-persistent memory devices. Memory 215 may include, but is not limited to: RAM 205, ROM 207, electronically erasable programmable read only memory (EEPROM), flash memory or other memory technology, optical disk storage, magnetic cassettes, magnetic tape, magnetic disk storage or other magnetic storage devices, or any other medium that may be used to store the desired information and that may be accessed by processor 203.

Communication interface 211 may include one or more transceivers, digital signal processors, and/or additional circuitry and software for communicating via any network, wired and/or wireless, using any protocol as described herein.

Processor 203 may include a single central processing unit (CPU), which may be a single-core or multi-core processor, or may include multiple CPUs. Processor(s) 203 and associated components may allow the computing device 200 to execute a series of computer-readable instructions to perform some or all of the processes described herein. The processor 203 may additionally or alternatively include one or more microprocessors, digital signal processors (DSPs), application-specific instruction set processors (ASIPs), graphics and/or image processors, or other hardware processors.

Although not shown in FIG. 2, various elements within memory 215 or other components in computing device 200, may include one or more caches, for example, CPU caches used by the processor 203, page caches used by the operating system 217, disk caches of a hard drive, and/or database caches used to cache content from database 221. For embodiments including a CPU cache, the CPU cache may be used by one or more processors 203 to reduce memory latency and access time. A processor 203 may retrieve data from or write data to the CPU cache rather than reading/writing to memory 215, which may improve the speed of these operations. In some examples, a database cache may be created in which certain data from a database 221 is cached in a separate smaller database in a memory separate from the database, such as in RAM 205 or on a separate computing device. For instance, in a multi-tiered application, a database cache on an application server may reduce data retrieval and data manipulation time by not needing to communicate over a network with a back-end database server. These types of caches and others may be included in various embodiments, and may provide potential advantages in certain implementations of devices, systems, and methods described herein, such as faster response times and less dependence on network conditions when transmitting and receiving data. Although various components of computing device 200 are described separately, functionality of the various components may be combined and/or performed by a single component and/or multiple computing devices in communication without departing from the disclosure.

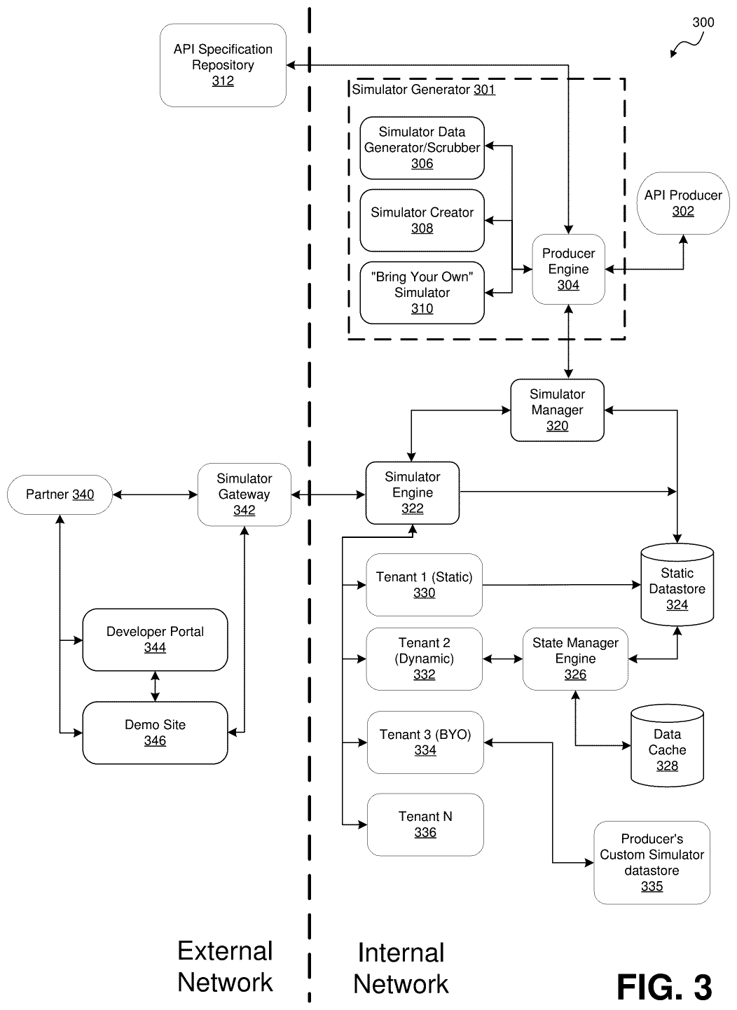

FIG. 3 shows an API simulation system 300 according to one or more aspects of the disclosure. The API simulation system 300 may include a simulator generator 301, a simulator manager 320, simulator engine 322, one or more tenancies 330, 332, 334, 336, state manager engine 326, static datastore 324, and/or data cache 328. Any of the components of the API simulation system 300 may be implemented, in whole or in part, using one or more computing systems described with respect to FIG. 2.

The simulator generator 301 may be configured to automatically generate a simulated API, for example, based on one or more API specifications (e.g. provided by API specification repository 312) and/or other data provided to (and/or obtained by) the simulator generator 301. The API specification(s) may include one or more parameters that define one or more functions and/or operations of a corresponding API, including defining one or more API responses, tasks, fields, and/or operations to be performed based on one or more corresponding API requests received by the API.

The simulator generator 301 may be configured to select one or more API specifications from the API specification repository 312, for example, based on one or more parameters, for example, provided to the simulator generator 301 by a user (e.g., API producer 302, partner 340, etc.). Although FIG. 3 illustrates that the API specification repository 312 is externally located with respect to the API simulation system 300, the API simulation system 300 may partially or entirely include the API specification repository 312 in one or more aspects. In one or more aspects, the contents of the API specification repository 312 are provided by a third party, but the API specification repository 312 is accessible by (and/or implemented in) the API simulation system 300.

The other data may be provided to the simulator generator 301 by, for example, a user (e.g. API producer 302, which may be a producer of an API). The API producer 302 may request the API to be simulated, for example, based on a request from a user (e.g., an external partner 340) interested in evaluating the API. The other data may include one or more parameters of the API, including, for example, one or more parameters defining API requests and/or API responses, request and/or response formats, one or more field parameters, whether the API is static (e.g. stateless) or dynamic (e.g. stateful), customer or other user data, or the like.

In an exemplary embodiment, the simulated API may be generated and/or adjusted using a machine learning (ML) model. The machine learning model may support a generative adversarial network, a bidirectional generative adversarial network, an adversarial autoencoder, or an equivalent thereof. Additionally, or alternatively, the machine learning model may be a convolutional neural network, a recurrent neural network, a recursive neural network, a long short-term memory (LSTM), a gated recurrent unit (GRU), an unsupervised pretrained network, a space invariant artificial neural network, or any equivalent thereof. The ML model may be trained based on input data and/or output data of the simulated API, such as one or more API requests and/or API responses, one or more API parameters, one or more API specifications, data entered via the user interface, feedback provided by one or more users via the user interface, and/or or other information. The machine learning model may be trained using different training techniques, such as supervised training, unsupervised training, semi-supervised training back propagation, transfer learning, stochastic gradient descent, learning rate decay, dropout, max pooling, batch normalization, and/or any equivalent deep learning technique.

In an exemplary embodiment, the simulator generator 301 may include a simulator data generator 306, a simulator creator 308, a supplied (“bring your own”) simulator processor 310, and/or a producer engine 304.

The producer engine 304 may be configured to control one or more components of the simulator generator 301, as well as request and/or retrieve one or more API specifications from the API specification repository 312. In an exemplary embodiment, the producer engine 304 may be configured to convert the API specification(s) to one or more other formats, such as a format usable by the user interface (e.g. demo site 346). For example, the producer engine 304 may convert an API specification in the YAML (YAML Ain't Markup Language) format to JSON (JavaScript Object Notation) format. The format conversion is not limited to these exemplary formats. The conversion may include generating necessary fields of the API, which may be implemented using the user interface. In one aspect, the conversion may include converting the data format and/or converting descriptions into implemented fields to facilitate the building of the API. As discussed below, the simulator creator 308 may alternatively perform the conversion operations, or may perform a portion of the conversion operations in collaboration with the producer engine 304.

The simulator data generator 306 may be configured to generate a dataset for use in the simulated API. The dataset may be a dummy dataset. In an exemplary embodiment, the dummy dataset is free of non-public information. Additionally, or alternatively, the simulator data generator 306 may be configured to anonymize, or scrub, a provided dataset by removing non-public information from the provided dataset. The dataset to be anonymized/scrubbed may be provided by, for example, the external user (e.g., partner 340) evaluating the simulated API, the internal user (e.g. API producer 302) requesting the creation of the simulated API, and/or another data source accessible to the API simulation system 300.

The simulator creator 308 may be configured to automatically create a simulated API, for example, based on one or more API specifications and/or other data provided by the producer engine 304. For example, the simulator creator 308 may generate the simulated API by converting the API specification(s) to a suitable format for implementation by the frontend (e.g. user interface and demo site 346). Alternatively, the producer engine 304 may at least partially perform the conversion operations and the simulator creator 308 may create the simulated API, for example, based on the converted API specification(s) provided by the producer engine 304. The simulator creator 308 may perform the conversion operations, or may perform a portion of the conversion operations in collaboration with the producer engine 304. Alternatively, the producer engine 304 may perform the conversion and provide the converted API specification(s) to the simulator creator 308. Again, the other data may include one or more parameters of the API, including, for example, one or more parameters defining API requests and/or API responses, request and/or response formats, one or more field parameters, whether the API is static (e.g. stateless) or dynamic (e.g. stateful), customer or other user data, or the like. For example, if the API to be simulated includes a unique field, the other data may include parameters (e.g. number of allowed characters, etc.) defining the field.

The supplied (“bring your own”-BYO) simulator processor 310 may be configured to process an API provided to the simulator generator 301 (e.g., from the API producer 302) to generate the simulated API. For example, if the API producer 302 has a completed API (e.g., that may not yet be ready for public release, such as an alpha/beta version of the API), this API may be used as a basis to generate a simulated API that may be evaluated by the external user (e.g., partner 340). This allows for the external user (e.g., partner 340) to evaluate the capabilities of the API without requiring the internal user to disclose the actual pre-production API.

The simulator manager 320 may be configured to control overall operation of the API simulation system 300, including controlling the operation of one or more components of the API simulation system 300. The simulator manager 320 may facilitate communications between the simulator generator 301 and the simulator engine 322. In an exemplary embodiment, the simulator manager 320 may be configured to generate one or more tenancies 330-336. The generation of the tenancies may be based on a determined type (e.g. static, dynamic, BYO) of the simulated API. The generation of the tenancies may include defining and/or assigning dedicated resources of the API simulation system 300 (and/or accessible by the system 300) to the respective tenancies. For example, the simulator manager 320 may provide a simulated API generated by the simulator generator 301 to the simulator engine 322, which may be configured to implement the simulated API by deploying the API to one of the dedicated tenancies 330-336 generated by the simulator manager 320. In an exemplary aspect, the API may be deployed to more than one tenancy. In an exemplary embodiment, the tenancies 330-336 may be deployed on separate servers, separate virtual machines, or other separated resources to improve security and contain potential issues of a simulation to only its dedicated compartment of resources.

The simulator engine 322 may be configured to facilitate and/or manage deployment of the simulated APIs among the dedicated tenancies 330-336. Additionally, or alternatively, the simulator engine 322 may be configured to manage communication between the external user(s) (via the simulator gateway 342) and the tenancies 330-336 in which APIs are deployed. The management of the communications may include processing API requests from the external user and processing corresponding API responses generated by the simulated API. The simulator engine 322 may perform data processing operations for data received from the simulator gateway 342, the simulator manager 320, and/or one or more of the tenancies 330-336. Although four tenancies 330, 332, 334, and 336 are illustrated, aspects may include fewer or additional tenancies. Further, the API simulation system 300 according to exemplary embodiments may include multiple tenancies of a particular type and/or omit one or more types of the tenancies.

For static (e.g. stateless) APIs, the simulator engine 322 may deploy the simulated API to a first (e.g., static) tenancy 330, which may be configured to host the API using dedicated resources. The first tenancy 330 may access the static datastore 324 to store data generated by the simulated API hosted within the first tenancy 330 and/or retrieve data requested by the simulated API.

For dynamic (e.g., stateful) APIs, the simulator engine 322 may deploy the simulated API to a second (dynamic) tenancy 332, which may be configured to host the API using dedicated resources. The second tenancy 332 may access a data cache 328 using state manager engine 326, and/or access the static datastore 324. The data cache 328 may store dynamic (stateful) data generated by the simulated API hosted within the second tenancy 332 and/or retrieve dynamic (stateful) data requested by the simulated API. The state manager engine 326 may be configured to: process requests by the simulated API deployed within the second tenancy 332, manage states generated by stateful API requests and/or responses, facilitate data communications between the tenancy 332 and the static datastore 324 and/or data cache 328, and/or perform other data processing operations. Similar to the discussion above with respect to the first tenancy 330, the static datastore 324 may store static data generated by the simulated API hosted within the second tenancy 332 and/or retrieve static data requested by the simulated API.

For BYO simulated APIs, the simulator engine 322 may deploy the simulated API to a third tenancy 334, which may be configured to host the API using dedicated resources. The third tenancy 334 may access a datastore 335, which may be associated with the API producer 302. As will be appreciated, for a stateful BYO API, the third tenancy 334 may utilize a state manager engine to manage stateful transactions produced by the BYO API. This state manager engine may be implemented by the state manager engine 326 or another dedicated state manager engine of the API simulation system 300 and/or provided by the API producer 302.

The API simulation system 300 may be accessed by one or more external users (e.g., partner 340) to evaluate an API simulated by the API simulation system 300. The external user(s) may access the simulated API using a simulator gateway 342 that is configured to facilitate communications between the external user(s) and the simulator engine 322. In an exemplary embodiment, the API simulation system 300 may be configured to generate a mock frontend (e.g., demo site 346) that is associated with the simulated API on the backend. The mock frontend (e.g., demo site 346) may mimic the external user's intended frontend to facilitate in the user evaluating the simulated API. This advantageously provides the user with a real-world demonstration of the simulated API that mimics the ultimate use case of the API by the user. For example, the mock frontend may be used to market and highlight new features of the simulated API to the user.

The mock frontend may be accessed, for example, using a developer portal 344 that is deployed by the API simulation system 300. The developer portal 344 may be a website made accessible to the external user (e.g., partner 340). The developer portal 344 may be configured to restrict or otherwise control access to the mock frontend (e.g., demo site 346), such as by requiring a unique login and password for the user (e.g., partner 340). In an exemplary embodiment, the external user may supply their own frontend which may access the simulated API using the simulator gateway 342. The user-supplied frontend may be hosted by the user (e.g., partner 340), may be hosted by a tenancy of the API simulation system 300, or a combination of both.

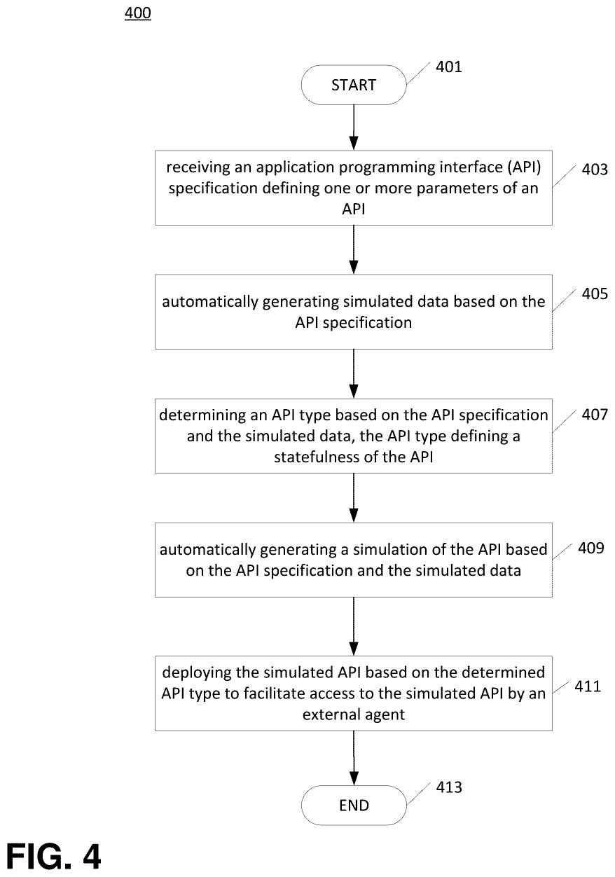

FIG. 4 shows a flow chart of a process for generating a simulated API according to one or more aspects of the disclosure. Some or all of the operations of process 400 may be performed using one or more computing devices as described herein.

The process begins at operation 401 and transitions to operation 403, where an application programming interface (API) specification may be received. The received API specification may define one or more parameters of an API. The API specification may be obtained from a repository (e.g., API specification repository 312) in one or more aspects.

At operation 405, simulated data may be automatically generated. The simulated data may be generated, for example, based on the API specification. Additionally, or alternatively, the simulated data may be generated based on other data, which may include one or more data parameters defining one or more data requirements and/or one or more data-field parameters (e.g., defining field constraints of a corresponding frontend interface). The other data may be obtained from, for example, the API producer 302, partner 340, and/or another data source and/or user.

In an exemplary embodiment, the generation of the simulated data may include anonymizing a dataset by removing non-public information from the dataset. Additionally, or alternatively, the generation of the simulated data may include generating a dummy dataset free of non-public information.

At operation 407, an API type may be determined. The API type may define a statefulness of the simulated API. The API type may be determined, for example, based on the API specification and/or the simulated data.

At operation 409, a simulation of the API may be automatically generated. The simulation of the API may be generated, for example, based on the API specification and/or the simulated data.

At operation 411, the simulated API is deployed to facilitate access to the simulated API by an external agent. The deployment may be based on the determined API type in one or more aspects. In an exemplary embodiment, the simulated API is deployed to a tenancy that includes one or more dedicated resources for the simulated API. The type of tenancy may be determined based on the API type. For example, if the API type is “dynamic,” the tenancy may be a dynamic tenancy that supports stateful API operations. In an exemplary embodiment, the deployment of the simulated API may include generating a simulated frontend interface configured for the simulated API. The frontend interface may be generated based on the API specification and/or the simulated data.

At operation 413, the process 400 ends. The process 400 may be repeated to generate one or more other simulated APIs.

One or more aspects discussed herein may be embodied in computer-usable or readable data and/or computer-executable instructions, such as in one or more program modules, executed by one or more computers or other devices as described herein. Generally, program modules include routines, programs, objects, components, data structures, and the like that perform particular tasks or implement particular abstract data types when executed by a processor in a computer or other device. The modules may be written in a source code programming language that is subsequently compiled for execution, or may be written in a scripting language such as (but not limited to) HyperText Markup Language (HTML) or XML. The computer executable instructions may be stored on a computer readable medium such as a hard disk, optical disk, removable storage media, solid-state memory, RAM, and the like. As will be appreciated by one of skill in the art, the functionality of the program modules may be combined or distributed as desired in various embodiments. In addition, the functionality may be embodied in whole or in part in firmware or hardware equivalents such as integrated circuits, field programmable gate arrays (FPGA), and the like. Particular data structures may be used to more effectively implement one or more aspects discussed herein, and such data structures are contemplated within the scope of computer executable instructions and computer-usable data described herein. Various aspects discussed herein may be embodied as a method, a computing device, a system, and/or a computer program product.

Although the present disclosure has been described in certain specific aspects, many additional modifications and variations would be apparent to those skilled in the art. In particular, any of the various processes described above may be performed in alternative sequences and/or in parallel (on different computing devices) in order to achieve similar results in a manner that is more appropriate to the requirements of a specific application. It is therefore to be understood that the present disclosure may be practiced otherwise than specifically described without departing from the scope and spirit of the present disclosure. Thus, embodiments of the present disclosure should be considered in all respects as illustrative and not restrictive. Accordingly, the scope of the disclosure should be determined not by the embodiments illustrated, but by the appended claims and their equivalents.

What is claimed is:

1. A computer-implemented method comprising:
receiving, by a simulator generator, an application programming interface (API) specification defining one or more parameters of an API;
automatically generating, by the simulator generator, simulated data based on the API specification;
determining, by a simulator manager, an API type based on the API specification and the simulated data, the API type defining a statefulness of the API;
automatically generating, by the simulator generator, a simulation of the API based on the API specification and the simulated data; and
deploying, by a simulator engine, the simulated API based on the determined API type to facilitate access to the simulated API by an external agent.

2. The computer-implemented method of claim 1, further comprising creating, based on the determined API type, a tenancy for the simulated API, wherein the tenancy comprises one or more dedicated resources for the simulated API.

3. The computer-implemented method of claim 2, wherein the tenancy is a dynamic tenancy configured to support a stateful API simulation.

4. The computer-implemented method of claim 1, further comprising:
receiving, by the simulator engine, an API request from external agent; and
providing, based on the API type, a stateful API response corresponding to the received API request using a state manager engine.

5. The computer-implemented method of claim 4, further comprising retrieving the stateful API response from a datastore using the state manager engine.

6. The computer-implemented method of claim 1, further comprising generating, based on the API specification and the simulated data, a simulated frontend interface, configured for the simulated API.

7. The computer-implemented method of claim 1, wherein generating the simulated data comprises anonymizing a dataset by removing non-public information from the dataset.

8. The computer-implemented method of claim 1, wherein generating the simulated data comprises generating a dummy dataset free of non-public information.

9. The computer-implemented method of claim 1, wherein generating the simulated data is based on at least one of: one or more data parameters defining one or more data requirements, or one or more data-field parameters defining field constraints of a corresponding frontend interface.

10. A computing device comprising:
one or more processors; and
memory storing instructions that, when executed by the one or more processors, configure the computing device to:
access an external specification datastore to receive an application programming interface (API) specification defining one or more parameters of an API;
automatically generate simulated data based on the API specification;
determine an API type based on the API specification and the simulated data, the API type defining a statefulness of the API;
automatically generate a simulation of the API based on the API specification and the simulated data;
creating, based on the API type, a tenancy for the simulated API;
deploy the simulated API using the created tenancy; and
enable access to the simulated API by an external computer device.

11. The computing device of claim 10, wherein the tenancy comprises one or more dedicated resources for the simulated API.

12. The computing device of claim 10, wherein the tenancy is a dynamic tenancy configured to support a stateful API simulation.

13. The computing device of claim 10, wherein the instructions, when executed by the one or more processors, configure the computing device to:
receive an API request from the external computing device; and
provide, based on the API type, a stateful API response, corresponding to the received API request, to the external computing device.

14. The computing device of claim 10, wherein the instructions, when executed by the one or more processors, configure the computing device to generate, based on the API specification and the simulated data, a simulated frontend interface, configured for the simulated API.

15. The computing device of claim 10, wherein the instructions, when executed by the one or more processors, configure the computing device to generate the simulated data by anonymizing a dataset by removing non-public information from the dataset.

16. The computing device of claim 10, herein the instructions, when executed by the one or more processors, configure the computing device to generate the simulated data by generating dummy data free of non-public information.

17. The computing device of claim 10, wherein generating the simulated data is further based on at least one of: one or more data parameters defining one or more data requirements, or one or more data-field parameters defining field constraints of a corresponding frontend interface.

18. One or more non-transitory media storing instructions that, when executed, cause a computing device to:
receive, by a simulator generator of the computing device and from a specification datastore, an application programming interface (API) specification defining one or more parameters of an API;
automatically generate, by the simulator generator, simulated data based on the API specification, wherein the generation of the simulated data includes removing non-public information from the simulated data;
determine, by a simulator manager of the computing device, an API type based on the API specification and the simulated data, the API type defining a statefulness of the API;
automatically generate, by the simulator generator, a simulation of the API based on the API specification and the simulated data;
deploy, by a simulator engine of the computing device, the simulated API for external access by an external computing device;
generate, by the simulator engine using the simulated API and based on an API request received from the external computing device, an API response; and
provide, by the simulator engine, the API response to the external computing device.

19. The one or more non-transitory media of claim 18, wherein the instructions, when executed, cause the computing device to create, based on the determined API type, a tenancy for the simulated API, wherein the tenancy comprises one or more dedicated resources for the simulated API.

20. The one or more non-transitory media of claim 18, wherein the instructions, when executed, cause the computing device to generate, based on the API specification and the simulated data, a simulated frontend interface configured for the simulated API.
